(19) United States
(12) Patent Application Publication
(10) Pub. No.: US 2008/0061034 A1
(43) Pub. Date: Mar. 13, 2008

(54) ETCHING APPARATUS AND ETCHING METHOD USING THE SAME

(75) Inventors: Dae-Sik JUNN, Gwangju-si (KR); Jeong-Beom LEE, Gwangju-si (KR); Sung-Ho CHA, Seoul (KR); Sung-Min NA, Yongin-si (KR); Myung-Gon SONG, Gwangju-si (KR); Duck-Ho KIM, Gwangju-si (KR); Kyoung-Jin LIM, Gwangju-si (KR)

Correspondence Address: MARGER JOHNSON & MCCOLLOM, P.C., 210 SW MORRISON STREET, SUITE 400, PORTLAND, OR, 97204, US

(73) Assignee: JUSUNG ENGINEERING CO., LTD., Gwangju-si (KR)

(21) Appl. No.: 11/852,012

(22) Filed: Sep. 7, 2007

(30) Foreign Application Priority Data
Sep. 8, 2006 (KR) 10-2006-86704
Sep. 6, 2007 (KR) 10-2007-90631

(51) Int. Cl. H01L 21/3065

(52) U.S. Cl. 216/60; 156/345.24; 156/345.34; 156/345.48

(57) ABSTRACT

An etching apparatus includes a chamber, a substrate support in the chamber, a substrate-screening unit over the substrate support, wherein a diameter of the substrate-screening unit is smaller than as or equals to a substrate, a gas injection means injecting gases onto a periphery of the substrate, a power supply unit providing an RF (radio frequency) power into the chamber, and a plurality of sensors sensing intervals between the substrate support and the substrate-screening unit.

### CROSS REFERENCE TO RELATED APPLICATIONS

The present invention claims the benefit of Korean Patent Application Nos. 10-2006-086704 filed on Sep. 8, 2006 and 10-2007-090631 filed on Sep. 6, 2007, which is hereby incorporated by references.

### BACKGROUND OF THE INVENTION

1. Field of the Invention

The present invention relates to a substrate processing apparatus for manufacturing semiconductor devices or liquid crystal display devices, and more particularly, to an etching apparatus that uniformly removes particles at edges of a substrate and an etching method using the same.

2. Discussion of the Related Art

In general, a semiconductor device or a flat panel display device is fabricated by depositing thin films on a surface of a substrate, such as wafer or glass, and then etching the thin films to thereby form thin film patterns.

During a deposition step of a thin film, the thin film is deposited substantially on an entire surface of the substrate. However, during an etching step of the thin film using an etching mask, the thin film is mainly etched on a central area of the substrate. Therefore, at edges of the substrate, the unremoved thin film may remain, and by-products or particles, which may be generated during the etching step, may accumulate. If next steps progress without removing such a thin film or particles accumulated at the edges of the substrate, the thin film or particles may peel off and may contaminate other areas of the substrate. Or the substrate may bend and may be misaligned.

To solve the problems, recently, an additional process of etching the edges of the substrate, which may be referred to as a bevel etching process, has been performed particularly in manufacturing semiconductor devices.

A method of etching the edges of a substrate is divided into wet-etching using etchant and dry-etching using plasma generated by gases. FIG. 1 illustrates an etching apparatus for edges of a substrate using plasma according to the related art.

A related art etching apparatus 100 includes a chamber 10 defining a reaction area, a substrate support 20 disposed in the chamber 10, and a gas distribution plate 30 disposed over the substrate support 20 and having a plurality of injection holes 32. The gas distribution plate 30 seals up an upper wall of the chamber 10. An exhaust line 12 is connected to a lower part of the chamber 10.

The substrate support 20 is movable up and down by an up-and-down driving unit 70. To expose edges of a substrate S to plasma, the substrate support 20 may have a smaller diameter than the substrate S.

The injection holes 32 are disposed along a periphery of the gas distribution plate 30 and are connected to a gas supply line 40, thereby injecting etching gases only around the edges of the substrate S. The gas supply line 40 is connected to a gas supply unit 50.

Further, an inert gas supply line (not shown) may be connected to a central portion of the gas distribution plate 30. The inert gas supply line may inject inert gases when the edges of the substrate S are etched, and thus a central portion of the substrate S may be prevented from being etched.

An RF (radio frequency) power source 60 is electrically connected to the substrate support 20, and an impedance matching system 62 is disposed between the substrate support 20 and the RF power source 60.

Meanwhile, a substrate-screening unit 31 is protruded from a bottom surface of the gas distribution plate 30. The substrate-screening unit 31 covers the central portion of the substrate S and makes only the edges of the substrate S exposed to plasma. The substrate-screening unit 31 may be formed as one united body with the gas distribution plate 30 or may be separately formed and then attached to the gas distribution plate 30. The substrate-screening unit 31 has a symmetrical shape to the substrate support 20 and has a diameter smaller than or equal to the substrate S.

Hereinafter, an etching method of edges of a substrate using the related art etching apparatus 100 will be described with reference to FIG. 2. FIG. 2 illustrates the etching apparatus in a process of etching the edges of the substrate according to the related art.

First, the substrate S is carried into the chamber 10 through a gate (not shown) and is disposed on the substrate support 20. The chamber 10 is under a vacuum condition by a vacuum pumping, and the substrate support 20 is raised to a process position by the up-and-down driving unit 70 as shown in FIG. 2. At this point, the substrate support 20 may be raised to a position such that a distance between the substrate S and the substrate-screening unit 31 may be within a range of about 0.2 mm to 0.5 mm. This is why radicals or ions of plasma generated at the edges of the substrate S are prevented from being diffused into the central portion of the substrate S and badly affecting a thin film pattern already formed on the central portion of the substrate S.

After raising the substrate support 20 to the process position, etching gases are injected through the injection holes 32 at the periphery of the gas distribution plate 30, and simultaneously, an RF power is applied to the substrate support 20 from the RF power source 60, whereby plasma is generated around the edges of the substrate S. The radicals or ions in the plasma etch and remove a thin film formed at the edges of the substrate S.

By the way, in the etching apparatus 100, because the distance between the substrate-screening unit 31 and the substrate S is very small at the process position, the substrate support 20 and the substrate-screening unit 31 should be highly processed, and intervals therebetween should be uniform at all points when the substrate support 20 and the substrate-screening unit 31 are set up.

If uniformity of the intervals between the substrate support 20 and the substrate-screening unit 31 is lowered, an etching rate at the edges of the substrate S varies according to locations. Therefore, to prevent the problem, the intervals between the substrate S and the substrate-screening unit 31 have been generally observed by a means, such as a sensor.

In a related art observing method, a transparent window is disposed at a side wall of the chamber, and a sensor is established on the outside of the transparent window. A distancing state may be monitored by analyzing patterns or intensities of a received laser light.

However, in the related art observing method, the intervals between the substrate S and the substrate-screening unit 31 are measured from sides thereof. Accordingly, it is difficult to exactly notice what the interval between the substrate S the substrate-screening unit 31 is at each point. Therefore, when it is decided that the distance is not uniform by the sensor, this causes a problem that the distance may be controlled by trial and error because there is no information about how which part is controlled.

Meanwhile, in the etching apparatus 100, widths of the edges of the substrate S to be etched should be uniform, and thus the edges of the substrate S exposed beyond the substrate-screening unit 31 may have uniform widths. To do this, substantially, a center of the substrate-screening unit 31 may coincide with a center of the substrate support 20. If the center of the substrate-screening unit 31 lies off that of the substrate support 20, the widths of the etched edges of the substrate S are not uniform even if etch uniformity is high.

In the related art, to align the centers with each other, assembly accuracy of components is checked in several steps during assembling the components. However, even though the components are precisely assembled under an atmosphere condition, the components deviate from initially set-up positions because the components such as O-rings or each element are pressed or modified by a vacuum pressure when the components are under a vacuum condition of an actual process mode.

Accordingly, recently, when the components of the apparatus are assembled, by etching a test substrate at a final inspection step, it is determined whether the widths of the edges of the substrate to be etched are uniform. However, there is a problem that it cannot be confirmed in real-time whether the centers of the substrate-screening unit 31 and the substrate support 20 are coincident in the chamber 10 before the test substrate is etched.

### SUMMARY OF THE INVENTION

Accordingly, the present invention is directed to an etching apparatus and an etching method using the same that precisely sense points at which intervals between a substrate support and a substrate-screening unit are not uniform.

An object of the present invention is to provide an etching apparatus and an etching method using the same that detect whether or not centers of the substrate support and the substrate-screening unit are coincident in real-time.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an etching apparatus includes a chamber, a substrate support in the chamber, a substrate-screening unit over the substrate support, wherein a diameter of the substrate-screening unit is smaller than or equals to a substrate, a gas injection means injecting gases onto a periphery of the substrate, a power supply unit providing an RF (radio frequency) power into the chamber, and a plurality of sensors sensing intervals between the substrate support and the substrate-screening unit.

In another aspect, an etching apparatus includes a chamber, a substrate support in the chamber, a substrate-screening unit over the substrate support, wherein a diameter of the substrate-screening unit is smaller than or equals to a substrate, a gas injection means injecting gases onto a periphery of the substrate, a power supply unit providing an RF power into the chamber, and a view port at a center of the substrate-screening unit, wherein the view port is used for detecting a coincidence between centers of the substrate-screening unit and the substrate support.

In another aspect, an etching method using an etching apparatus, which includes a chamber, a substrate support in the chamber, a substrate-screening unit over the substrate support, a gas injection means injecting gases onto a periphery of a substrate to be disposed on the substrate support, a power supply unit providing an RF power into the chamber; a plurality of sensors sensing intervals between the substrate support and the substrate-screening unit, a level-controlling unit connected to the substrate support, a view port at a center of the substrate-screening unit for detecting a coincidence of centers of the substrate-screening unit and the substrate support, and a horizontal driving unit horizontally moving the substrate support with respect to the substrate-screening unit, includes forming a vacuum condition in the chamber, first controlling a first distance between the substrate support and the substrate-screening unit using the plurality of sensors and the level-controlling unit such that the intervals equal to one another, first aligning the substrate support with the substrate-screening unit using the view port and the horizontal driving unit, loading the substrate on the substrate support, moving the substrate support such that the substrate has a second distance from the substrate-screening unit, and removing particles at edges of the substrate by generating plasma.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a view of illustrating an etching apparatus for edges of a substrate using plasma according to the related art;

FIG. 2 is a view of illustrating the etching apparatus in a process of etching the edges of the substrate according to the related art;

FIG. 3 is a view of schematically illustrating an etching apparatus according to a first embodiment of the present invention;

FIG. 4 is a cross-sectional view of illustrating a substrate support including sensors within according to the first embodiment of the present invention;

FIG. 5 is a perspective view of illustrating a substrate support including sensors within according to the first embodiment of the present invention;

FIG. 6 is a view of schematically illustrating an etching apparatus according to another example of the first embodiment of the present invention;

FIG. 7 is a view of schematically illustrating an etching apparatus according to another example of the first embodiment of the present invention; and

FIG. 8 is a view of schematically illustrating an etching apparatus according to a second embodiment of the present invention.

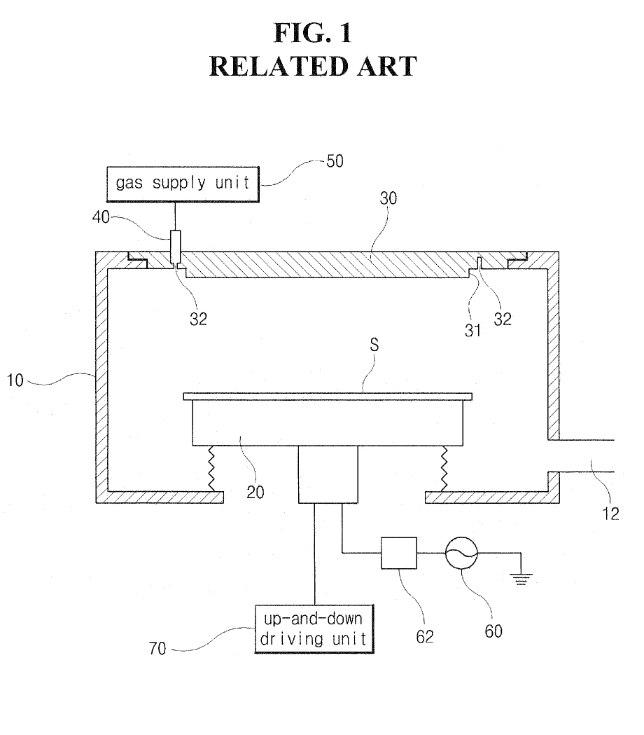

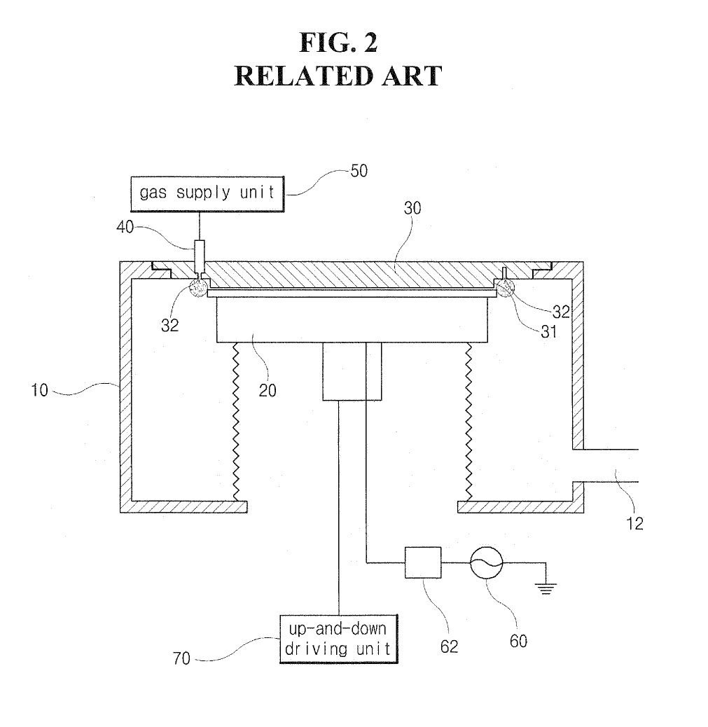

### DETAILED DESCRIPTION OF THE PREFERRED EMBODIMENTS

Reference will now be made in detail to the preferred exemplary embodiments, examples of which are illustrated in the accompanying drawings.

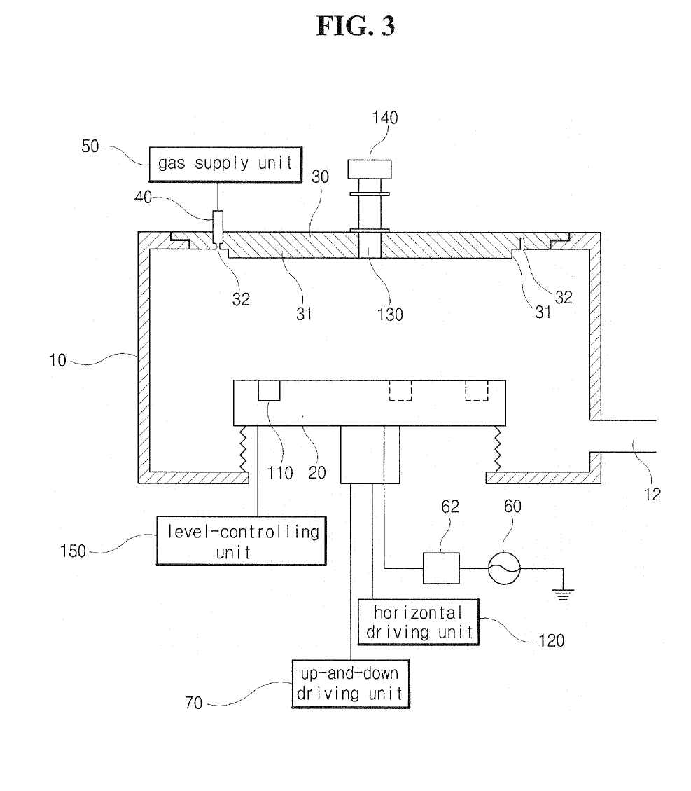

FIG. 3 is a view of schematically illustrating an etching apparatus according to a first embodiment of the present invention. In FIG. 3, the same parts as the related art may have the same references, and explanation of the same parts may be omitted.

An etching apparatus 100 includes a chamber 10, a substrate support 20, which may be referred to as a susceptor, disposed in the chamber 10, and a gas distribution plate 30 disposed over the substrate support 20 and having a plurality of injection holes 32. The gas distribution plate 30 and the substrate support 20 function as electrodes.

The etching apparatus 100 further includes a plurality of sensors 110 in the substrate support 20 so that intervals between the substrate support 20 and a substrate-screening unit 31 may be measured at several points and it may be checked at which point the interval is not the same as others.

The substrate-screening unit 31 is protruded from a bottom surface of the gas distribution plate 30. The substrate-screening unit 31 may be formed as one united body with the gas distribution plate 30 or may be separately formed and then attached to the gas distribution plate 30. The substrate-screening unit 31 has a symmetrical shape to the substrate support 20 and has a diameter smaller than or equal to a substrate S disposed on the substrate support 20.

During the process, the substrate-screening unit 31 comes very close to the substrate support 20, which an RF power from the RF power source 60 is applied to. Therefore, to prevent electric arcs between the substrate support 20 and the substrate-screening unit 31, the substrate-screening unit 31 may be formed of or its surface may be treated with a dielectric material such as aluminum oxide (Al₂O₃).

In addition, the substrate support 20, beneficially, may have a smaller diameter than the substrate S, and it is desirable that the diameter of the substrate support 20 may be smaller than that of the substrate-screening unit 31.

The substrate S should be disposed on the substrate support 20 such that the center of the substrate S coincides with the center of the substrate support 20.

A distance between the substrate support 20 and the substrate-screening unit 31 may have a very precise margin of error within 10 micrometers over all, and thus the sensors 110, desirably, may have a resolution of about 1 micrometer.

In general, a sensor may be classified into a contact-type and a noncontact-type. In the present invention, a noncontact-type sensor may be adopted as the sensors 110 by considering that the substrate S is disposed on the substrate support 20. A noncontact-type sensor having the above-mentioned resolution may include a laser optical sensor and an eddy current sensor.

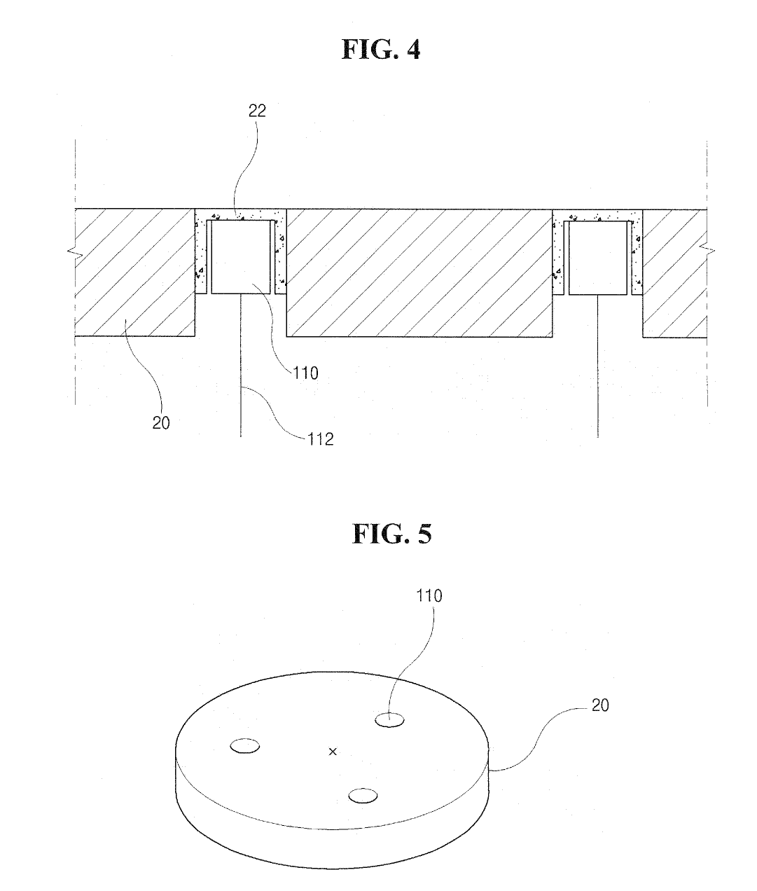

It is desirable for a vacuum condition or their durability that the sensors 110 are not exposed in the reaction area. Therefore, as shown in FIG. 4, through-holes are formed in the substrate support 20, and vacuum seal walls 22 are disposed in the through-holes such that the vacuum seal walls 22 seal up upper portions of the through-holes. Then, the sensors 110 are set up under the vacuum seal walls 22 in the through-holes, respectively. A signal line 112 is connected to each sensor 110 to transmit sensed data to a controller (not shown).

The vacuum seal walls 22 may be selectively formed of a transparent or opaque material depending on a kind of the sensors 110. For example, in case of a laser optical sensor, if the laser optical sensor detects wavelengths of visible light, the vacuum seal walls 22 may be formed of a transparent material, and if the laser optical sensor detects wavelengths of ultraviolet light or infrared light, the vacuum seal walls 22 may be formed of either a transparent material or an opaque material. Alternatively, in case of an eddy current sensor, the vacuum seal walls 22 may be formed of either a transparent material or an opaque material but cannot be formed of a metallic material.

Like this, if the vacuum seal walls 22 are formed in the substrate support 20 and the sensors 110 are set up under the vacuum seal walls 22, there is less limitation on drawing the signal lines 112 out as compared with the case that the sensors 110 are exposed to the vacuum. This brings about advantages in designing.

To achieve the objects of the present invention for detecting points of non-uniform intervals, it is desirable that a plurality of sensors 110 may be set up, and more beneficially, more than three sensors 110 may be set up.

FIG. 5 shows a substrate support including sensors within according to the first embodiment of the present invention. In FIG. 5, three sensors 110 are disposed in the substrate support 20 such that the sensors 110 are equidistant from the center of the substrate support 20 and one of the sensors 110 are at equal distances from the others. The more sensors 110 may be set up, the more accurate points, at which the intervals are not uniform, can be detected.

The sensed data may be transmitted from the sensors 110 and may be visually displayed on a monitor of a computer. Accordingly, an administrator of the apparatus can check the distance between the substrate support 20 and the substrate screening unit 31 in real-time.

When the distance between the substrate support 20 and the substrate-screening unit 31 is needed to be adjusted, the substrate support 20 may be leveled by a level-controlling unit 150. The level-controlling unit 150 controls a height of a certain part of the substrate support 20 up and down. For example, pillars are set up as the level-controlling unit 150 to support a lower surface of the substrate support 20 at least three points, wherein the pillars are independently connected to respective driving means, such as a motor, a pneumatic cylinder, or a hydraulic cylinder.

Alternatively, when adjusting the distance between the substrate support 20 and the substrate-screening unit 31 is required, a height of the gas distribution plate 30 may be changed at a corresponding point.

Meanwhile, the etching apparatus 100 according to the first embodiment of the present invention has another feature that the etching apparatus 100 includes a view port 130 at a center of the gas distribution plate 30, more particularly, at a center of the substrate-screening unit 31.

The view port 130 is required for checking whether the centers of the substrate-screening unit 31 and the substrate support 20 are coincident by seeing with the naked eye or a camera therethrough from the outside of the chamber 10. The view port 130 may be formed by inserting a transparent window such as quartz into a through portion formed in the gas distribution plate 30. The view port 130 may be vacuum-sealed by an O-ring.

A first mark (not shown) such as a “+” shape is marked at the center of an upper surface of the substrate support 20, and a second mark (not shown) corresponding to the first mark is marked at the view port 130. Seeing in through the view port 130, it is easily checked if the centers of the substrate-screening unit 31 and the substrate support 20 are coincident from coincidence of the first and second marks. The coincidence of the centers of the substrate-screening unit 31 and the substrate support 20 in a vacuum condition may be checked after the chamber 10 is closed and a vacuum pumping is accomplished, even if a test substrate is not directly etched.

To avoid annoyance of checking everything with the naked eye, a camera 140 may be set up over the view port 130, and the coincidence may be checked by displaying images taken from the camera 140 on a screen.

When it is checked through the view port 130 that the centers of the substrate-screening unit 31 and the substrate support 20 are not coincident, the substrate support 20 may be moved horizontally by a horizontal driving unit 120 so that the centers of the substrate-screening unit 31 and the substrate support 20 are coincident to each other without taking the apparatus apart. The horizontal driving unit 120 moves the substrate support 20 along an x-axis or a y-axis using a driving means, such as a motor, a pneumatic cylinder, or a hydraulic cylinder, which is operated by a user or automatically controlled by a controlling unit.

Accordingly, the coincidence of the centers can be checked in real-time under the vacuum condition. In addition, since the positions of the elements can be adjusted without taking the apparatus apart, time for adjusting the elements can be reduced.

Alternatively, to make the centers of the gas distribution plate 30 and the substrate support 20, the gas distribution plate 30 may be moved horizontally in place of the substrate support 20.

Hereinafter, operation of the etching apparatus 100 will be described with reference to FIG. 3.

Referring to FIG. 3, it is first checked whether the distance between the substrate support 20 and the substrate-screening unit 31 is uniform before a substrate is carried into the etching apparatus 100. To do this, after the chamber 10 is pumped and is under a vacuum condition, the sensors 110 are operated, and some values are measured from the sensors 110. The measured values are compared with each other or with a reference value. When the distance between the substrate support 20 and the substrate-screening unit 31 is not uniform as a result of comparison, the distance is controlled by the level-controlling unit 150. This step may be referred as a distance-controlling step.

It is also previously checked whether the centers of the substrate-screening unit 31 and the substrate support 20 are coincident. This is performed through the view port 130 by the naked eye or a camera. More particularly, it is checked whether or not the first mark of the substrate support 20 is coincident with the second mark of the view port 130. When the first mark is not coincident with the second mark, the substrate support 20 may be moved horizontally by the horizontal driving unit 120 such that the first and second marks are coincident with each other. This step may be referred to as a center-controlling step.

After the distance-controlling step and the center-controlling step, a rechecking step will be performed. In other words, it is checked again whether the distance between the substrate support 20 and the substrate-screening unit 31 is uniform and the centers of the substrate-screening unit 31 and the substrate support 20 are coincident. In this step, remeasured values are compared with reference values, and when the remeasurced values are not within a margin of error, a gate of the chamber 10 is not open so that a substrate is not carried into the chamber 10.

Then, a substrate (not shown) is carried into the chamber 10 and is loaded on the substrate support 20. Next, the substrate support 20 is moved up such that a distance between the substrate support 20 and the substrate-screening unit 31 is within a range of 0.2 mm to 0.5 mm.

Etching gases are injected onto edges of the substrate through the injection holes 32. An RF power is applied to the substrate support 20, and plasma is generated to thereby etch the edges of the substrate, more particularly, particles or a thin film at the edges of the substrate.

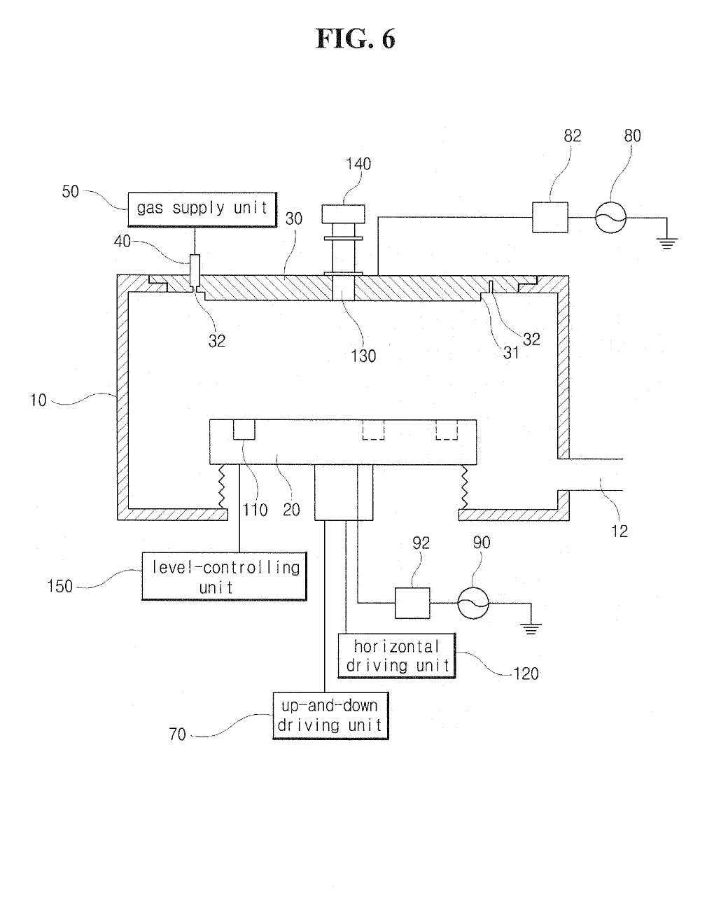

Meanwhile, another example of the first embodiment of the present invention is shown in FIG. 6. FIG. 6 is a view of schematically illustrating an etching apparatus according to another example of the first embodiment of the present invention. In FIG. 6, a first RF power source 80 is electrically connected to the gas distribution plate 30 that functions as an upper electrode, and a second RF power source 90 is electrically connected to the substrate support 20 that functions as a lower electrode, while the RF power source 60 is electrically connected to only the substrate support 20 in the example of FIG. 3. The first RF power source 80 is used for generation of plasma, and the second RF power source 90 is used for bias. A first impedance matching system 82 and a second impedance matching system 92 are connected to output portions of the first RF power source 80 and the second RF power source 90, respectively.

Using the second RF power source 90 for bias makes it easy to control ion energies, and thus an etching efficiency can be increased.

To use the gas distribution plate 30 as an upper electrode, the gas distribution plate 30 may be formed of a metallic material such as aluminum (Al). On the other hand, to prevent arcing, the substrate-screening unit 31 may be coated with a nonconductive material or may be formed of a nonconductive material and connected to the gas distribution plate 30.

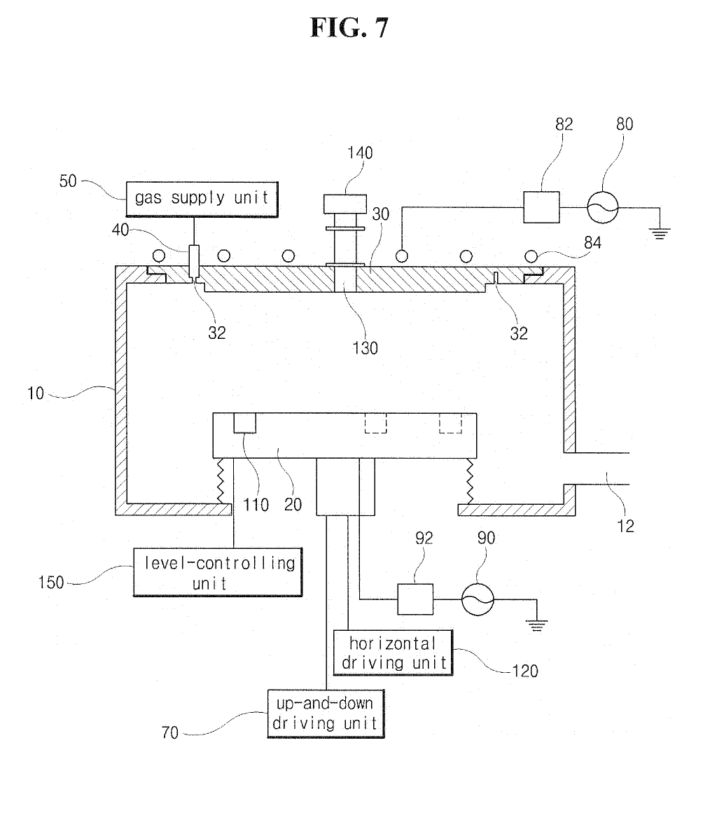

FIG. 7 illustrates an etching apparatus according to another example of the first embodiment of the present invention. In FIG. 7, an antenna 84 is disposed over the gas distribution plate 30 so that inductively-coupled plasma may be generated. Here, the gas distribution plate 30 may be formed of a nonconductive material.

Even though the etching apparatus includes the gas distribution plate 30 having injection holes 32 at its periphery, a plurality of injectors may be formed at side walls of the chamber 10 of the etching apparatus.

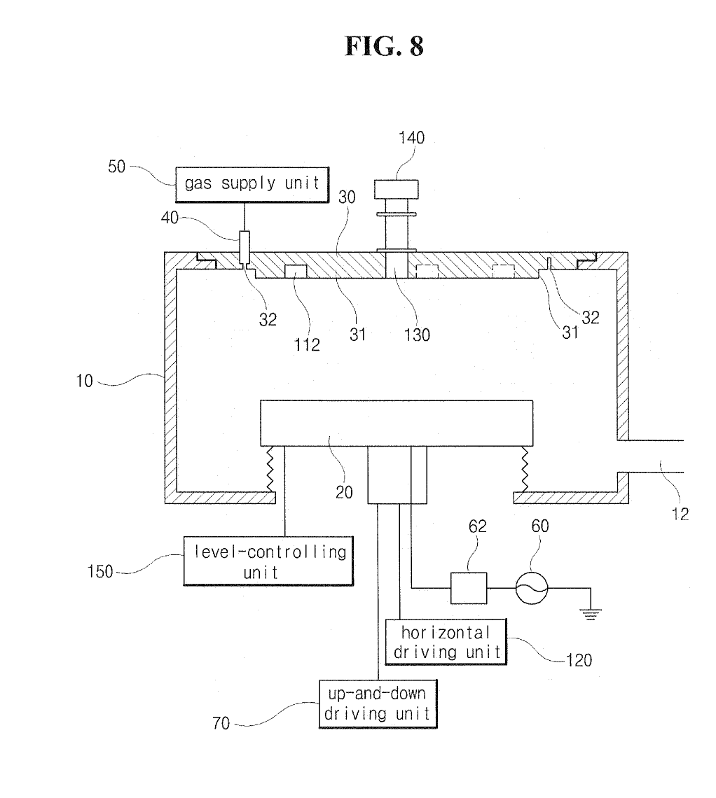

FIG. 8 is a view of schematically illustrating an etching apparatus according to a second embodiment of the present invention. The etching apparatus of FIG. 8 has the same structure as that of FIG. 3 except for a position of sensors. The same parts may have the same references, and explanation of the same parts may be omitted.

In FIG. 8, the etching apparatus 100 includes a plurality of sensors 112 in the substrate-screening unit 31. From the sensors 112, intervals between the substrate support 20 and the substrate-screening unit 31 may be measured at several points, and it may be checked whether the distance is uniform or not. When the distance is not uniform, a height of either the substrate support 20 or the substrate-screening unit 31 may be controlled. The sensors 112 may have the same structure as those of FIG. 4.

According to the etching apparatus of the present invention, points at which the distance between the substrate support and the substrate-screening unit is not uniform can be detected in real-time. In addition, the distance can be easily controlled by the level-controlling unit connected to the substrate support without taking the apparatus apart.

Moreover, it can be checked in real-time whether the centers of the substrate support and the substrate-screening unit are coincident, and the centers can be coincident with each other using the horizontal driving unit connected to the substrate support without taking the apparatus apart.

It will be apparent to those skilled in the art that various modifications and variations can be made in the apparatus without departing from the spirit or scope of the invention. Thus, it is intended that the present invention covers the modifications and variations of this invention provided they come within the scope of the appended claims and their equivalents.

What is claimed is:

1. An etching apparatus, comprising:
a chamber;
a substrate support in the chamber;
a substrate-screening unit over the substrate support, wherein a diameter of the substrate-screening unit is smaller than or equals to a substrate;
a gas injection means injecting gases onto a periphery of the substrate;
a power supply unit providing an RF (radio frequency) power into the chamber; and
a plurality of sensors sensing intervals between the substrate support and the substrate-screening unit.

2. The apparatus according to claim 1, wherein the plurality of sensors are disposed in the substrate support.

3. The apparatus according to claim 2, wherein the substrate support includes a plurality of through-holes, each through-hole is sealed up by a vacuum seal wall, and each sensor is disposed under the vacuum seal wall in the through-hole.

4. The apparatus according to claim 1, wherein the plurality of sensors are disposed in the substrate-screening unit.

5. The apparatus according to claim 1, wherein the plurality of sensors include one of a laser optical sensor and an eddy current sensor.

6. The apparatus according to claim 1, further comprising a level-controlling unit connected to the substrate support, wherein the level-controlling unit includes at least three parts, each of which independently controls a height of the substrate support at each of the at least three parts.

7. The apparatus according to claim 1, wherein the power supply unit includes an RF power source electrically connected to the substrate support and an impedance matching system disposed between the substrate support and the RF power source.

8. The apparatus according to claim 1, wherein the gas injection means includes a gas distribution plate sealing up an upper wall of the chamber and having injection holes, wherein the substrate-screening unit is connected to a bottom surface of the gas distribution plate, and the injection holes are disposed along a periphery of the gas distribution plate such that the injection holes surround the substrate-screening unit.

9. The apparatus according to claim 1, wherein the power supply unit includes a first RF power source electrically connected to the substrate support, a first impedance matching system disposed between the substrate support and the first RF power source, a second RF power source electrically connected to the gas injection means, and a second impedance matching system disposed between the gas injection means and the second RF power source, wherein the first RF power source is used for generation of plasma, and the second RF power source is used for bias.

10. The apparatus according to claim 1, wherein the power supply unit includes an antenna outside the chamber.

11. An etching apparatus, comprising:
a chamber;
a substrate support in the chamber;
a substrate-screening unit over the substrate support, wherein a diameter of the substrate-screening unit is smaller than or equals to a substrate;
a gas injection means injecting gases onto a periphery of the substrate;
a power supply unit providing an RF power into the chamber; and
a view port at a center of the substrate-screening unit, wherein the view port is used for detecting a coincidence between centers of the substrate-screening unit and the substrate support.

12. The apparatus according to claim 11, wherein the substrate support has a first mark at a center thereof, and the view port has a second mark at a center thereof.

13. The apparatus according to claim 11, further comprising a horizontal driving unit horizontally moving the substrate support with respect to the substrate-screening unit.

14. The apparatus according to claim 11, further comprising a camera over the view port outside the chamber.

15. An etching method using an etching apparatus, which includes a chamber, a substrate support in the chamber, a substrate-screening unit over the substrate support, a gas injection means injecting gases onto a periphery of a substrate to be disposed on the substrate support, a power supply unit providing an RF power into the chamber; a plurality of sensors sensing intervals between the substrate support and the substrate-screening unit, a level-controlling unit connected to the substrate support, a view port at a center of the substrate-screening unit for detecting a coincidence of centers of the substrate-screening unit and the substrate support, and a horizontal driving unit horizontally moving the substrate support with respect to the substrate-screening unit, the method comprising:
forming a vacuum condition in the chamber;
first controlling a first distance between the substrate support and the substrate-screening unit using the plurality of sensors and the level-controlling unit such that the intervals equal to one another;
first aligning the substrate support with the substrate-screening unit using the view port and the horizontal driving unit;
loading the substrate on the substrate support;
moving the substrate support such that the substrate has a second distance from the substrate-screening unit; and
removing particles at edges of the substrate by generating plasma.

16. The method according to claim 15, farther comprising second controlling the first distance between the substrate support and the substrate-screening unit and second aligning the substrate support with the substrate-screening unit before loading the substrate on the substrate support.
